(19) United States
(12) Patent Application Publication
(10) Pub. No.: US 2023/0207248 A1
(43) Pub. Date: Jun. 29, 2023

(54) SUBSTRATE TREATING APPARATUS AND SUBSTRATE TREATING METHOD

(71) Applicant: SEMES CO., LTD., Cheonan-si (KR)

(72) Inventors: Young Je UM, Busan (KR); Min Sung HAN, Hwaseong-si (KR); Seong Gil LEE, Hwaseong-si (KR); Wan Jae PARK, Hwaseong-si (KR); Dong Sub OH, Busan (KR); Yoon Jong JU, Hwaseong-si (KR); Myoung Sub NOH, Hwaseong-si (KR)

(73) Assignee: SEMES CO., LTD., Cheonan-si (KR)

(21) Appl. No.: 17/973,985

(22) Filed: Oct. 26, 2022

(30) Foreign Application Priority Data
Dec. 28, 2021 (KR) 10-2021-0189899

(51) Int. Cl. H01J 37/02; H01J 37/32

(52) U.S. Cl. CPC H01J 37/02; H01J 37/3244; H01J 37/32467; H01J 2237/32

(57) ABSTRACT

An exemplary embodiment of the present invention provides a substrate treating apparatus, including: a chamber having an inner space; a shower head for partitioning the inner space into an upper first zone and a lower second zone, and formed with a plurality of through holes; a support unit for supporting a substrate in the second zone; a gas supply unit for supplying gas to the first zone; a plasma source for forming a plasma in the first zone by exciting the gas; and an adsorption plate coupled to the shower head, in which a surface of the adsorption plate is provided with a material that adsorbs radicals contained in the plasma.

### CROSS-REFERENCE TO RELATED APPLICATIONS

This application claims priority to and the benefit of Korean Patent Application No. 10-2021-0189899 filed in the Korean Intellectual Property Office on Dec. 28, 2021, the entire contents of which are incorporated herein by reference.

### TECHNICAL FIELD

The present invention relates to a substrate treating apparatus and a substrate treating method, and more particularly, to a substrate treating apparatus and a substrate treating method, which treat a substrate with plasma.

### BACKGROUND ART

Plasma refers to an ionized gas state composed of ions, radicals, and electrons. Plasma is generated by very high temperatures, strong electric fields, or RF Electromagnetic Fields. A semiconductor device manufacturing process may include an etching process of removing a thin film or a foreign material formed on a substrate, such as a wafer, by using plasma. The etching process is performed in which ions and/or radicals of plasma collide with the thin film on the substrate or react with the thin film.

In general, various films including a natural oxide film are stacked and formed on the substrate. Various processes for treating the substrate by using plasma require appropriate selectivity for each process. The selectivity is determined according to the degree of etching of the films formed on the substrate. Some of the films formed on the substrate may be etched by an etchant formed by reacting radicals (or plasma) and treatment gas with each other. In addition, other portions of the films formed on the substrate may be etched by radicals. The target etched by the etchant and the target etched by the radical are different. Accordingly, it is important to control the ratio of the etchant and the radicals applied to the substrate in order to control the selectivity suitable for the substrate.

### SUMMARY OF THE INVENTION

The present invention has been made in an effort to provide a substrate treating apparatus and a substrate treating method, which are capable of efficiently treating a substrate.

The present invention has also been made in an effort to provide a substrate treating apparatus and a substrate treating method, which are capable of efficiently absorbing ultraviolet rays generated from plasma.

The present invention has also been made in an effort to provide a substrate treating apparatus and a substrate treating method, which are capable of adjusting the amount of radicals between radicals and an etchant acting on a substrate.

The present invention has also been made in an effort to provide a substrate treating apparatus and a substrate treating method, which are capable of adjusting selectivity of a substrate by attaching and detaching an adsorption plate that adsorbs radicals according to a process and replacing the adsorption plate with an adsorption plate suitable for the process.

The problem to be solved by the present invention is not limited to the above-mentioned problems, and the problems not mentioned will be clearly understood by those skilled in the art from the descriptions below.

An exemplary embodiment of the present invention provides a substrate treating apparatus, including: a chamber having an inner space; a shower head for partitioning the inner space into an upper first zone and a lower second zone, and formed with a plurality of through holes; a support unit for supporting a substrate in the second zone; a gas supply unit for supplying gas to the first zone; a plasma source for forming a plasma in the first zone by exciting the gas; and an adsorption plate coupled to the shower head, in which a surface of the adsorption plate is provided with a material that adsorbs radicals contained in the plasma.

According to the exemplary embodiment, the surface of the adsorption plate may be provided with a material different from a material of the shower head.

According to the exemplary embodiment, the gas may contain a fluorine element, and the radical may contain a fluorine radical.

According to the exemplary embodiment, the material may include nickel (Ni) or titanium (Ti), and the adsorption plate may adsorb the fluorine radical.

According to the exemplary embodiment, the gas may further contain hydrogen ions, and the adsorption plate may adsorb hydrogen ions in the gas.

According to the exemplary embodiment, the adsorption plate may be disposed to be in contact with an upper surface of the shower head.

According to the exemplary embodiment, the adsorption plate may be provided detachably from the shower head.

According to the exemplary embodiment, a plurality of through holes may be formed in the adsorption plate, and the through hole may be positioned to overlap the through hole when viewed from the top.

According to the exemplary embodiment, the plasma source may include: an ion blocker disposed above the shower head to partition the first zone into an upper plasma formation space and a lower mixing space, and grounded; and an upper electrode which is disposed above the ion blocker and to which power is applied.

According to the exemplary embodiment, the gas supply unit may include: a first gas supply unit for supplying first gas to the plasma formation space; and a second gas supply unit for supplying second gas to the mixing space, and the plasma source may excite the first gas to form the plasma, and the ion blocker may trap ions included in the plasma formed in the plasma formation space and allow radicals to pass to the mixing space.

Another exemplary embodiment of the present invention provides a substrate treating apparatus, including: a chamber having an inner space; a support unit for supporting the substrate in the inner space; an upper electrode to which high-frequency power is applied; an ion blocker disposed under the upper electrode and grounded; a shower head disposed under the ion blocker and above the support unit, and formed with a plurality of through holes; a first gas supply unit for supplying first gas to a space between the upper electrode and the ion blocker; a second gas supply unit for supplying second gas to a space between the ion blocker and the shower head; and an adsorption plate provided on an upper surface of the shower head, in which a region between the upper electrode and the ion blocker may be provided as a plasma formation space in which a plasma is formed from the first gas, a region between the ion blocker and the shower head may be provided as a mixing space in which radicals included in the plasma and the second gas react to form an etchant, a substrate treating region, in which a substrate is treated by the etchant, may be provided under the shower head, and a surface of the adsorption plate may be provided with a material capable of adsorbing specific ions contained in the first gas and the second gas, and radicals.

According to the exemplary embodiment, the specific ion may include a hydrogen ion and the radical may include a fluorine radical.

According to the exemplary embodiment, the material may include nickel (Ni) or titanium (Ti).

According to the exemplary embodiment, the adsorption plate may be provided detachably from the shower head, a plurality of through holes may be formed in the adsorption plate, and the through hole may be positioned to overlap the through hole when viewed from the top, and a diameter of the through hole may be provided to be larger than a diameter of the through hole.

Still another exemplary embodiment of the present invention provides a method of treating a substrate formed with a first film and a second film that is different from the first film, the method including: generating a plasma in a first space within a chamber by exciting first gas, and allowing radicals to flow to a second space within the chamber by blocking ions included in the plasma, in which some components of the radical supplied to the second space are adsorbed to and removed on a surface of the adsorption plate provided in the second space.

According to the exemplary embodiment, some other components of the radicals supplied to the second space may react with second gas supplied to the second space to form an etchant, and some still other components of the radicals supplied to the second space may flow into a third space where the substrate is located.

According to the exemplary embodiment, the etchant may be supplied to the third space to remove the first film between the first film and the second film.

According to the exemplary embodiment, the radical flowing into the third space may remove the second film between the first film and the second film.

According to the exemplary embodiment, the surface of the adsorption plate may be coated with a material capable of adsorbing the radical.

According to the exemplary embodiment, the first film may include an oxide film, the first gas may contain fluorine, the second gas may contain ammonia, and the radical may include a fluorine radical.

According to the exemplary embodiment of the present invention, it is possible to efficiently treat the substrate.

Further, according to the exemplary embodiment of the present invention, it is possible to efficiently absorb ultraviolet rays generated from plasma.

Further, according to the exemplary embodiment of the present invention, it is possible to adjust the amount of radicals between radicals and an etchant acting on a substrate.

Further, according to the exemplary embodiment of the present invention, it is possible to adjust selectivity of a substrate by attaching and detaching an adsorption plate that adsorbs radicals according to a process and replacing the adsorption plate with an adsorption plate suitable for the process.

The effect of the present invention is not limited to the foregoing effects, and those skilled in the art may clearly understand non-mentioned effects from the present specification and the accompanying drawings.

### BRIEF DESCRIPTION OF THE DRAWINGS

FIG. 1 is a diagram schematically illustrating a substrate treating apparatus according to an exemplary embodiment of the present invention.

FIG. 2 is a diagram schematically illustrating a shower head and an adsorption plate of FIG. 1 viewed from the front.

FIG. 3 is a diagram schematically illustrating a state in which plasma is formed in a plasma formation space by exciting first gas in the substrate treating apparatus of FIG. 1.

FIG. 4 is a diagram schematically illustrating a state in which an etchant is formed by supplying second gas to a mixing space in the substrate treating apparatus of FIG. 1.

FIG. 5 is an enlarged view of portion A of FIG. 4 schematically illustrating the case where radicals flowing in the mixing space in the substrate treating apparatus are adsorbed to an adsorption plate.

FIG. 6 is a diagram schematically illustrating the substrate treating apparatus according to another exemplary embodiment of FIG. 1.

FIG. 7 is a diagram schematically illustrating the substrate treating apparatus according to another exemplary embodiment of FIG. 1.

### DETAILED DESCRIPTION

Hereinafter, an exemplary embodiment of the present invention will be described in more detail with reference to the accompanying drawings. An exemplary embodiment of the present invention may be modified in various forms, and the scope of the present invention should not be construed as being limited by the exemplary embodiment described below. The present exemplary embodiment is provided to more completely explain the present invention to those skilled in the art. Therefore, the shapes of components in the drawings are exaggerated to emphasize a clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

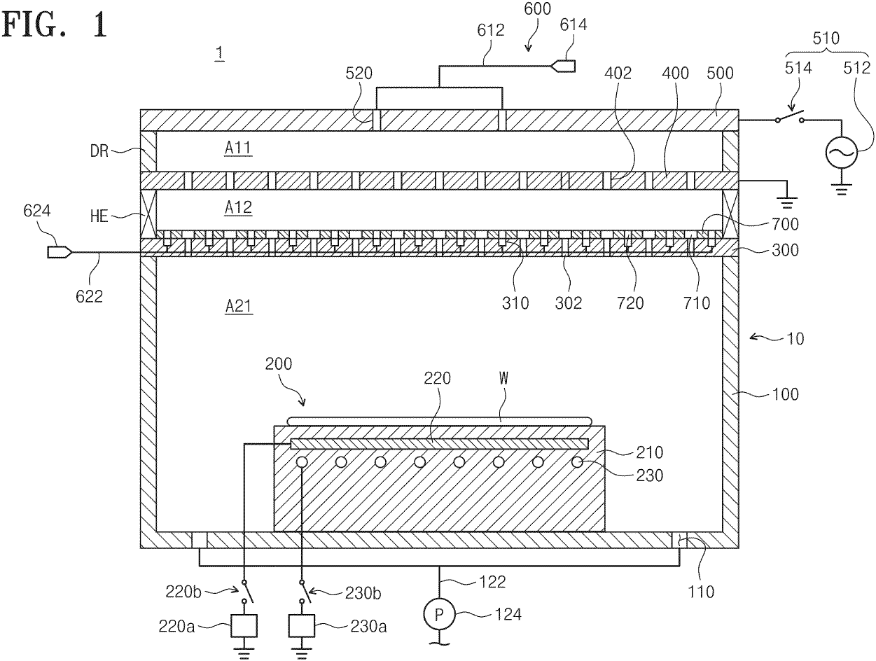

Hereinafter, an exemplary embodiment of the present invention will be described in detail with reference to FIGS. 1 to 7.

FIG. 1 is a diagram schematically illustrating a substrate treating apparatus according to an exemplary embodiment of the present invention. Referring to FIG. 1, a substrate treating apparatus 1 according to the exemplary embodiment of the present invention treats a substrate W. The substrate treating apparatus 1 may treat the substrate W by using plasma. For example, the substrate treating apparatus 1 may perform an etching process for removing a thin film on the substrate W by using plasma, an ashing process for removing a photoresist film, a deposition process for forming a thin film on the substrate W, or a dry cleaning process. However, the present invention is not limited thereto, and the plasma treatment process performed by the substrate treating apparatus 1 may be variously modified into a known plasma treatment process. As the substrate W loaded into the substrate treating apparatus 1, the substrate W on which the treatment process has been partially performed may be loaded. For example, the substrate W loaded into the substrate treating apparatus 1 may be a substrate W on which an etching process or a photo process has been performed.

The substrate treating apparatus 1 may include a housing 100, a support unit 200, a shower head 300, an ion blocker 400, an upper electrode 500, and a gas supply unit 600.

The chamber 10 may have an inner space. The inner space of the chamber 10 may be divided into an upper first zone A1 and a lower second zone A2 by the shower head 300 to be described later. The chamber 10 may be collectively defined by components involved in defining the first zone A1 and the second zone A2. The first zone A1 may be divided into an upper plasma formation space A11 and a lower mixing space A12 by an ion blocker 400 to be described later.

The plasma formation space A11 may be defined as a space in which the upper electrode 500 and the ion blocker 400, which will be described later, are combined with each other. The plasma formation space A11 may be provided as a space in which the plasma P is generated. The mixing space A12 may be defined as a space formed by combining the ion blocker 400 and the shower head 300 with each other. The mixing space A12 may be provided as a space in which radicals R included in a plasma P generated in the plasma formation space A11 and second gas G2 to be described later react with each other to form an etchant E.

The second zone A2 may be defined as a space formed by combining the shower head 300 and the housing 100 to be described later. The second area A2 may be defined as a treatment space A21 in which the substrate W is treated. The treatment space A21 may be a space in which the substrate W is located. In the treatment space A21, the substrate W may be treated by the radical R and/or the etchant E.

The housing 100 may define the treatment space A21. For example, the housing 100 may be combined with the shower head 300 to be described later to define the treatment space A21. The support unit 200 to be described later is disposed in the treatment space A21 defined by the housing 100. The housing 100 may be provided in a generally cylindrical shape. For example, the housing 100 may have a cylindrical shape with an open top.

An inner wall of the housing 100 may be coated with a material that is capable of preventing the housing 100 from being etched by the plasma P. For example, the inner wall of the housing 100 may be coated with a dielectric film, such as ceramic. The housing 110 may be grounded. An opening (not illustrated) through which the substrate W is unloaded from the treatment space A21 or the substrate W is loaded into the treatment space A21 may be formed in the housing 100. The opening (not illustrated) may be selectively opened/closed by a door (not illustrated).

An exhaust hole 110 is formed in the bottom surface of the housing 100. The exhaust hole 110 may be connected to an exhaust unit 120. The exhaust unit 120 discharges particles and process by-products flowing through the treatment space A21. The exhaust unit 120 may adjust the pressure of the treatment space A21. The exhaust unit 120 may include an exhaust line 122 and a decompression member 124. One end of the exhaust line 122 may be connected to the exhaust hole 110, and the other end of the exhaust line 122 may be connected to the decompression member 124. The decompression member 123 may be a pump. However, the present invention is not limited thereto, and may be provided with various modifications which are known devices for providing negative pressure.

The support unit 200 is located inside the treatment space A21. The support unit 200 supports the substrate W in the treatment space A21. The support unit 200 may be an ESC capable of chucking the substrate W using electrostatic force. The support unit 200 may heat the supported substrate W.

The support unit 200 may include a body 210, an electrostatic electrode 220, and a heater 230. The body 210 supports the substrate W. The body 210 has a support surface for supporting the substrate W on the upper surface. The substrate W is seated on the upper surface of the body 210. The body 210 may be provided with a dielectric substance. The body 210 may be provided as a disk-shaped dielectric plate. For example, the body 210 may be made of a ceramic material. The electrostatic electrode 220 and the heater 230, which will be described later, may be embedded in the body 210.

The electrostatic electrode 220 may be provided at a position overlapping the substrate W when viewed from the top. The electrostatic electrode 220 may be disposed above the heater 230. The electrostatic electrode 220 is electrically connected to a first power source 220a. The first power source 220a may include a DC power source. A first switch 220b is installed between the electrostatic electrode 220 and the first power source 220a. The electrostatic electrode 220 may be electrically connected to the first power source 220a by turning on/off the first switch 220b. For example, when the first switch 220b is turned on, a direct current is applied to the electrostatic electrode 220. When a current is applied to the electrostatic electrode 220, an electric field by electrostatic force capable of chucking the substrate W may be formed in the electrostatic electrode 220. The electric field may transmit attractive force by which the substrate W is chucked in a direction toward the body 210 to the substrate W. Accordingly, the substrate W is adsorbed to the body 210.

The heater 230 heats the substrate W. The heater 230 may heat the substrate W supported on the upper surface of the body 210. The heater 230 heats the substrate W by increasing the temperature of the body 210. The heater 230 is electrically connected to the second power source 230a. A second switch 230b is installed between the heater 230 and the second power source 230a. The heater 230 may be electrically connected to the second power source 230a by turning on/off the second switch 230b. The heater 230 generates heat by resisting the current applied from the second power source 230a.

The generated heat is transferred to the substrate W through the body 210. The substrate W may be maintained at a temperature required for the process by the heat generated by the heater 230. In addition, the heater 230 increase the temperature of the body 210 to prevent impurities (for example, an oxide film) separated from the substrate W from re-adhering to the substrate W while the substrate W is treated. The heater 230 may be a heating element, such as tungsten. However, the type of the heater 230 is not limited thereto, and the heater may be variously modified and provided with known heating elements.

Although not illustrated, according to the exemplary embodiment, a plurality of heaters 230 may be provided as spiral coils. The heaters 230 may be provided in different regions of the body 210, respectively. For example, the heater 230 for heating a central region of the body 210 and the heater 230 for heating an edge region of the body 210 may be provided, and the heaters 230 may independently adjust the degree of heating from each other.

In the above-described example, it has been described that the heater 230 is provided in the body 210 as an example, but the present invention is not limited thereto. For example, the heater 230 may not be provided in the body 210.

The shower head 300 may be disposed in an upper portion of the housing 100. The shower head 300 may be disposed between the ion blocker 400 and the treatment space A21 to be described later. The shower head 300 may divide the inner space of the chamber 10 into the upper first zone A1 and the lower second zone A2. For example, a space formed by combining the shower head 300 and the housing 100 may be defined as the treatment space A21. In addition, a space formed by combining the shower head 300 and the ion blocker 400 to be described later may be defined as the mixing space A12.

The shower head 300 may be formed in a generally circular shape when viewed from the top. For example, the shower head 300 may be provided in a disk shape. According to the exemplary embodiment, the shower head 300 may be made of a material of stainless steel.

A through hole 302 may be formed in the shower head 300. A plurality of through holes 302 may be provided. The plurality of through holes 302 may be formed to extend from an upper surface to a lower surface of the shower head 300. That is, the plurality of through holes 302 may be formed through the shower head 300. The plurality of through holes 302 may communicate a fluid from the upper mixing space A12 to the lower treatment space A21.

A lower gas inlet 310 may be formed in the shower head 300. At least one lower gas inlet 310 may be provided. The lower gas inlet 310 may be connected to a second gas line 622 to be described later. The lower gas inlet 310 may communicate with a gas hole 710 formed in an adsorption plate 700 to be described later. The lower gas inlet 310 may supply second gas G2 to be described later toward the mixing space A12. The lower gas inlet 310 may communicate with the mixing space A12, but may be configured not to communicate with the treatment space A21. The lower gas inlet 310 may be disposed between the plurality of through holes 302. That is, the lower gas inlet 310 may be formed at a position that does not overlap the plurality of through holes 302.

The heating member HE may be disposed in an upper portion of the shower head 300. The heating member HE may be a heater having a ring shape when viewed from the top. The heating member HE may increase the temperature of the mixing space A12. The heating member HE generates heat to increase the temperature of the mixing space A12 to increase the mixing efficiency of the plasma P from which ions are removed and the second gas G2.

The ion blocker 400 may be disposed above the shower head 300. In addition, the ion blocker 400 may be disposed above the heating member HE. The ion blocker 400 may be disposed between the shower head 300 and the upper electrode 500 to be described later. The ion blocker 400 may divide the first zone A1 into the upper plasma formation space A11 and the lower mixing space A12. For example, a space formed by combining the ion blocker 400, the shower head 300, and the heating member HE may be defined as the mixing space A12. For example, a space formed by combining the ion blocker 400, the adsorption plate 700 to be described later, and the heating member HE may be defined as the mixing space A12.

The ion blocker 400 may be grounded. The ion blocker 400 may function as an electrode opposite to the upper electrode 500 to be described later. Accordingly, the ion blocker 400 may function as a plasma source forming plasma P together with the upper electrode 500.

A hole 402 may be formed in the ion blocker 400. The hole 402 may pass through an upper end and a lower end of the ion blocker 400. The plasma P formed in the plasma formation space A11 may flow from the plasma formation space A11 to the mixing space A12 through the hole 402. The ion blocker 400 may adsorb ions (or electrons) included in the plasma P passing through the hole 402 and ions and electrons in the radicals R. Accordingly, only the radical R among the components included in the plasma P may pass through the ion blocker 400. The ion blocker 400 may function to block the passage of ions.

The upper electrode 500 may have a plate shape. The upper electrode 500 may be located above the inner space of the chamber 10. The upper electrode 500 may be disposed above the ion blocker 400. The upper electrode 500 may be disposed to face the ion blocker 400. The insulating member DR made of as an insulating material may be disposed between the upper electrode 500 and the ion blocker 400. The insulating member DR may have a ring shape when viewed from the top. The insulating member DR may electrically insulate the ion blocker 400 and the upper electrode 500 from each other. A space formed by combining the upper electrode 500, the insulating member DR, and the ion blocker 400 may be defined as the plasma formation space A11.

A power module 510 may be provided to the upper electrode 500. The power module 510 may apply power to the upper electrode 500. The power module 510 may include an upper power supply 512 and an upper power switch 514. The upper power supply 512 may be provided as an RF supply. The upper power supply 512 may apply a high frequency current to the upper electrode 500. An impedance matcher (not illustrated) may be provided between the upper electrode 500 and the upper power source 512. A high-frequency current is applied to the upper electrode 500 according to the on/off of the upper power switch 514. When a high-frequency current is applied to the upper electrode 500, an electric field is formed between the ion blocker 400 functioning as the opposite electrode and the upper electrode 500. Accordingly, plasma may be generated by exciting the first gas G1 to be described later in the plasma formation space A11.

An upper gas inlet 520 may be formed in the upper electrode 500. At least one upper gas inlet 520 may be provided. The upper gas inlet 520 may be connected to the first gas line 622 to be described later. The upper gas inlet 520 may supply the first gas G1 toward the plasma formation space A11.

The gas supply unit 600 supplies gas to the inner space of the chamber 10. For example, the gas supply unit 600 may supply the first gas G1 to the plasma formation space A11 and supply the second gas G2 to the mixing space A12. The gas supply unit 600 may include a first gas supply unit 610 and a second gas supply unit 620. Hereinafter, a gas supplied by the first gas supply unit 610 is defined as the first gas G1, and a gas supplied by the second gas supply unit 620 is defined as the second gas G2. The first gas G1 may be referred to as process gas. The second gas G2 may be referred to as treatment gas.

The first gas supply unit 610 supplies the first gas G1 to the plasma formation space A1. The first gas supply unit 610 may supply the first gas G1 to the plasma formation space A11 that is a space between the upper electrode 500 and the ion blocker 400. The first gas supply unit 610 may include a first gas line 612 and a first gas supply source 614.

The first gas line 612 connects the first gas supply source 624 and the upper gas inlet 520 to each other. One end of the first gas line 622 may be connected to each of the plurality of upper gas inlets 520, and the other end of the first gas line 622 may be connected to the first gas supply source 612.

The first gas supply source 614 supplies the first gas G1 to the plasma formation space A11 through the first gas line 612. The first gas G1 may include a fluorine-based element. For example, the first gas G1 may be nitrogen trifluoride (NF₃) or fluorine (F₂) gas. Optionally, the first gas G1 may further include any one or a plurality of Ar, H₂, and He. The first gas G1 supplied to the plasma formation space A11 may be excited by the upper electrode 500 and the ion blocker 400.

The second gas supply unit 620 may supply the second gas G2 to the mixing space A12. The second gas supply unit 620 may supply the second gas G2 to the mixing space A12 that is a space between the ion blocker 400 and the shower head 300. For example, the second gas supply unit 620 may supply the second gas G2 to the mixing space A12 that is a space between the ion blocker 400 and the adsorption plate 700 to be described later. The second gas supply unit 620 may include the second gas line 622 and the second gas supply source 624.

The second gas line 622 connects the second gas supply source 624 and the lower gas inlet 310 to each other. One end of the second gas line 622 may be connected to each of the plurality of lower gas inlets 310, and the other end of the second gas line 622 may be connected to the second gas supply source 624.

The second gas supply source 624 supplies the second gas G2 to the mixing space A12 through the second gas line 622. The second gas G2 may include a hydrogen-based element. For example, the second gas G2 may be ammonia (NH₃) gas. Optionally, the second gas G2 may further include inert gas, such as H₂ or He. The inert gas included in the second gas G2 may function as carrier gas. The second gas G2 supplied to the second space A2 may react with the radicals R to form the etchant E.

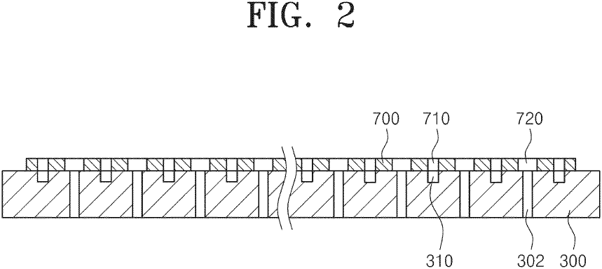

FIG. 2 is a diagram schematically illustrating the shower head and the adsorption plate of FIG. 1 viewed from the front. Hereinafter, the adsorption plate according to the exemplary embodiment of the present invention will be described in detail with reference to FIGS. 1 and 2.

The adsorption plate 700 may be coupled to the shower head 300. The adsorption plate 700 may be coupled to the upper surface of the shower head 300. The lower surface of the adsorption plate 700 may be in contact with the upper surface of the shower head 300. The adsorption plate 700 may be provided detachably from the shower head 300. The adsorption plate 700 may be provided in a substantially disk shape. As an example, the adsorption plate 700 may be provided in the shape of a disk having a small thickness. When viewed from the top, the adsorption plate 700 may have a shape substantially corresponding to the shower head 300, and the adsorption plate 700 may have a diameter corresponding to the shower head 300.

The adsorption plate 700 may be coated. The surface of the adsorption plate 700 may be coated with a material that adsorbs a specific radical R. For example, the radicals R included in the plasma P generated in the plasma formation space A11 may be adsorbed on the surface of the adsorption plate 700. According to the exemplary embodiment, the surface of the adsorption plate 700 may be coated with a material including nickel (Ni). Optionally, the surface of the adsorption plate 700 may also be coated with a material including titanium (Ti). The material coated on the surface of the adsorption plate 700 may be provided with a material different from that of the shower head 300.

The adsorption plate 700 may absorb a component including ultraviolet light (UV) flowing through the mixing space A12. In addition, the adsorption plate 700 may block the components including ultraviolet light (UV) from flowing from the mixing space A12 to the treatment space A21. A detailed mechanism by which the radicals R are adsorbed by the adsorption plate 700 will be described later.

A gas hole 710 and a through hole 720 may be formed in the adsorption plate 700. At least one gas hole 710 may be provided. The gas hole 710 may pass through the adsorption plate in the vertical direction. The gas hole 710 may communicate with the lower gas inlet 310. The gas hole 710 may be formed at a position overlapping the lower gas inlet 310 at a location in which the adsorption plate 700 is coupled to the shower head 300. The gas hole 710 may allow the second gas G2 supplied from the lower gas inlet 310 to flow into the mixing space A12.

At least one through hole 720 may be provided. For example, a plurality of through holes 720 may be provided. The through hole 720 may be formed to penetrate from the upper surface to the lower surface of the adsorption plate 700. The through hole 720 may be positioned to overlap the through hole 302 formed in the shower head 300 when viewed from the top. A diameter of the through hole 720 may be provided relatively larger than a diameter of the through hole 302. Optionally, the diameter of the through hole 720 may be provided to correspond to the diameter of the through hole 302. The etchant E formed in the mixing space A12 may be supplied to the treatment space A21 through the through hole 720. In addition, the radical R flowing through the mixing space A12 may pass through the through hole 720 and be supplied to the treatment space A21. The detailed mechanism for this will be described below.

In the above-described example, it has been described that the adsorption plate 700 is coupled to the upper surface of the shower head 300 as an example, but the present invention is not limited thereto. For example, the adsorption plate 700 may be coupled to each of the upper and lower surfaces of the shower head 300. Optionally, the adsorption plate 700 may be coupled to the lower surface of the shower head 300.

Hereinafter, the substrate treating method according to the exemplary embodiment of the present invention will be described in detail. The substrate treating method described below may be performed in the substrate treating apparatus 1 according to the exemplary embodiment described with reference to FIGS. 1 to 2.

The substrate W used in the substrate treating method described below may have a first film and a second film. The first film may be a silicon oxide film (for example, SiO₂). In addition, the second film may be various films formed on the substrate W, such as a polysilicon film or a nitride film. However, this is for convenience of description, and various films may be stacked on the substrate W to be formed.

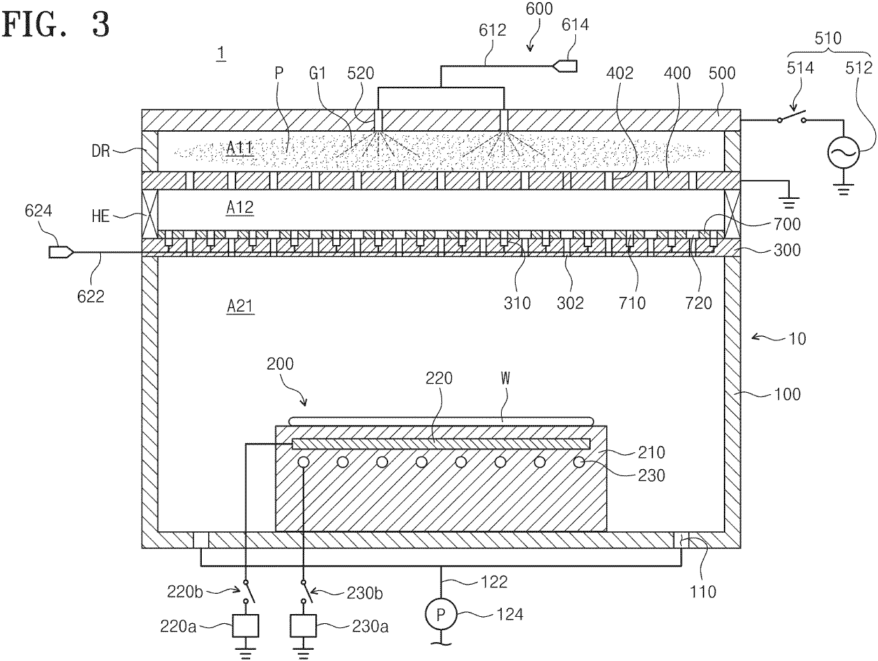

FIG. 3 is a diagram schematically illustrating a state in which plasma is formed in the plasma formation space by exciting first gas in the substrate treating apparatus of FIG. 1. Referring to FIG. 3, the first gas supply unit 610 supplies the first gas G1 to the plasma formation space A11.The first gas G1 may be supplied to the plasma formation space A11 through the upper gas inlet 520 formed in the upper electrode 500. The first gas G1 according to the exemplary embodiment of the present invention may include fluorine. For example, the first gas G1 supplied to the plasma formation space A11 may be gas including nitrogen trifluoride (NF₃) gas. In addition, inert gas may be further supplied to the plasma formation space A11.The inert gas supplied to the plasma formation space A11 may function as carrier gas.

The first gas G1 supplied to the plasma formation space A11 is excited into the plasma P by the upper electrode 500 to which the high frequency power is applied and the grounded ion blocker 400. That is, as the first gas G1 is transited to the plasma P state, the first gas G1 is decomposed into ions, electrons, and radicals. As an example, as the nitrogen trifluoride (NF₃) gas is transited to the plasma P state, F radicals may be formed in the plasma formation space A11.

The plasma P formed in the plasma formation space A11 flows into the mixing space A12 through the hole 402 formed in the grounded ion blocker 400. In the process in which the plasma P passes through the hole 402, ions and electrons among the components of the plasma P are absorbed. As the plasma P passes through the ion blocker 400, only the radicals among ions, electrons, and radicals included in the plasma P may be supplied to the mixing space A12. Accordingly, only F radicals may be supplied to the mixing space A12.

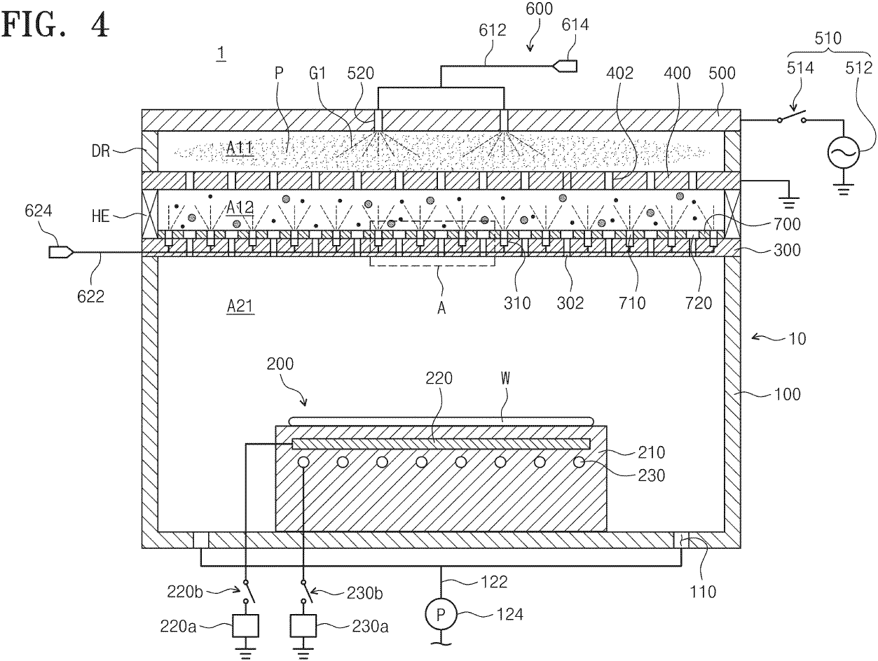

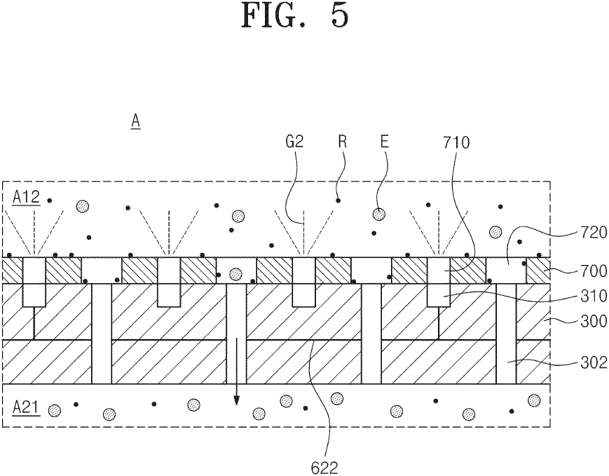

FIG. 4 is a diagram schematically illustrating a state in which an etchant is formed by supplying the second gas to the mixing space in the substrate treating apparatus of FIG. 1. FIG. 5 is an enlarged view of portion A of FIG. 4 schematically illustrating the case where radicals flowing in the mixing space in the substrate treating apparatus are adsorbed to the adsorption plate.

Referring to FIGS. 4 and 5, the second gas supply unit 620 supplies the second gas G2 to the mixing space A12. The second gas G2 may be supplied to the mixing space A12 through the lower gas inlet 310 formed in the shower head 300 along the gas hole 710 formed in the adsorption plate 700. The second gas G2 according to the exemplary embodiment of the present invention may include hydrogen. For example, the second gas G2 supplied to the mixing space A12 may be gas including ammonia (NH₃) gas. In addition, inert gas may be further supplied to the mixing space A12. The inert gas supplied to the mixing space A12 may function as carrier gas.

Some components of the radicals R supplied to the mixing space A12 may react with the second gas G2 supplied to the mixing space A12. For example, the ammonia (NH₃) gas supplied to the mixing space A12 may react with F radicals flowing through the mixing space A12 to form the etchant E. The etchant E may be ammonium fluoride (NH₄F). Optionally, the etchant E may be ammonium hydrogen fluoride (NH4F.HF).

The etchant E generated in the mixing space A12 flows from the mixing space A12 to the treatment space A21. The etchant E may act on the substrate W positioned in the treatment space A21. Among the first film and the second film formed on the substrate W, the first film and the etchant E may interact with each other. For example, NH₄F may react with a silicon oxide film (for example, SiO₂) formed on the substrate W to generate a reactant of (NH4)₂SiF₆. The generated reactant may be removed from the substrate W. Accordingly, the etchant E supplied to the treatment space A21 may act on the first film formed on the substrate W to remove the first film from the substrate W.

In addition, some other components of the radicals R supplied to the mixing space A12 are in contact with the surface of the adsorption plate 700 positioned below the mixing space A12. The radicals R that is in contact with the surface of the adsorption plate 700 may be adsorbed to the adsorption plate 700.

For example, the surface of the adsorption plate 700 according to the exemplary embodiment of the present invention may be made of nickel (Ni). Hydrogen ions derived from the inert gas including hydrogen are adsorbed on the surface of the adsorption plate 700, and the hydrogen ions may be bound to F radicals again. Accordingly, some components of the F radicals flowing in the mixing space A12 may be adsorbed to the adsorption plate 700. The position of the adsorbed F radical is fixed in the mixing space A12. Accordingly, the F radicals adsorbed on the adsorption plate 700 do not flow to the treatment space A21. That is, as the adsorption plate 700 adsorbs the F radicals, the number of F radicals supplied to the treatment space A21 and acting on the substrate W may be reduced.

Some still other components of the radicals R supplied to the mixing space A12 may not be adsorbed on the surface of the adsorption plate 700 and may not react with the second gas G2. That is, other still other components of the radicals R supplied to the mixing space A12 may flow from the mixing space A12 to the treatment space A21. For example, the F radicals supplied to the treatment space A21 may react with the second film among the first film and the second film formed on the substrate W. For example, the F radical may react with the polysilicon film formed on the substrate W to generate a reactant of SiF₄. The generated reactant may be removed from the substrate W. Accordingly, the radicals supplied to the treatment space A21 may act on the second film formed on the substrate W to remove the second film from the substrate W.

In general, various films including a natural oxide film may be stacked on the substrate W. In various processes of treating the substrate W by using plasma, an appropriate selectivity is required for each process. The selectivity is determined according to the degree of etching of the films formed on the substrate W. The films formed on the substrate W may be etched by the etchant E and the radicals R. The target etched by the etchant E and the target etched by the radical R are different.

Accordingly, according to the exemplary embodiment of the present invention, by adsorbing the radicals R included in the plasma P by using the adsorption plate 700, the number of radicals acting on the substrate W may be reduced. Accordingly, a relatively small amount of radicals R may act on the substrate W. On the other hand, the etchant E generated by the reaction of the radicals R and the second gas G2 in the mixing space A12 may act on the substrate W relatively much. Accordingly, the selectivity between the film etched by the radical R (for example, the second film) and the film etched by the etchant E (for example, the first film) among the films formed on the substrate W may be easily adjusted.

In addition, in the exemplary embodiment, the present invention has been described based on the case where the surface of the adsorption plate 700 is coated with a nickel (Ni) material to adsorb the F radicals contained in the plasma (P) as an example. The adsorption plate 700 according to the example may be provided detachably from the shower head 300. In addition, the material of the surface of the adsorption plate 700 may be variously changed according to the type of radical to be adsorbed. Accordingly, it is possible to smoothly adjust the selectivity by replacing the adsorption plate to the adsorption plate 700 coated with a suitable material according to the selectivity of the substrate W required in various processes, the selection ratio can be smoothly adjusted.

A substrate treating apparatus according to another exemplary embodiment of the present invention described below is provided in a substantially similar manner to the configuration of the above-described substrate treating apparatus except for additional described cases. Accordingly, in order to avoid duplication of content, a description of the overlapping configuration will be omitted.

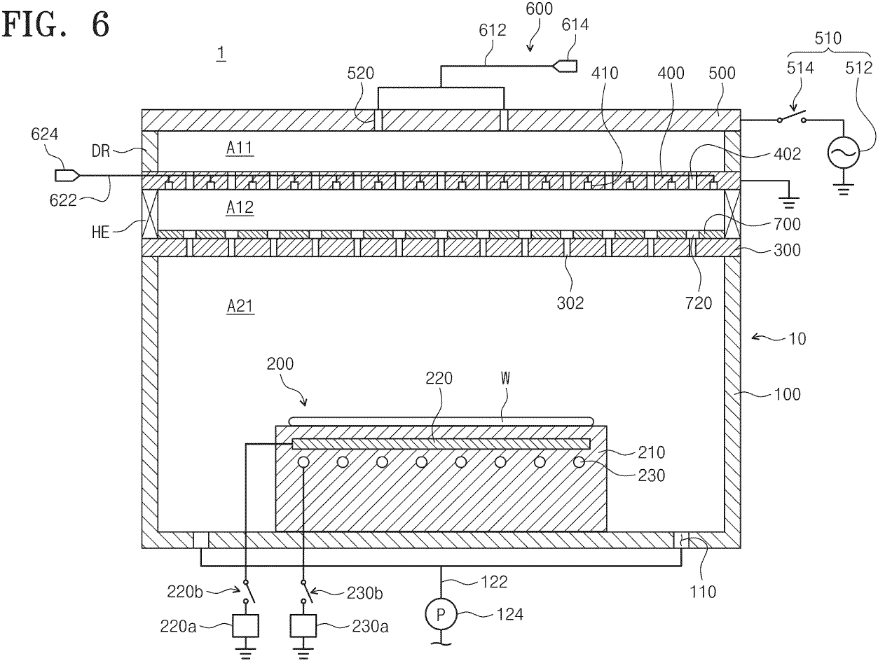

FIG. 6 is a diagram schematically illustrating the substrate treating apparatus according to another exemplary embodiment of FIG. 1. Referring to FIG. 6, the shower head 300 may have a substantially circular shape when viewed from the top. For example, the shower head 300 may be provided in a disk shape. According to the exemplary embodiment, the shower head 300 may be made of a material of stainless steel.

A through hole 302 may be formed in the shower head 300. A plurality of through holes 302 may be provided. The plurality of through holes 302 may be formed to extend from an upper surface to a lower surface of the shower head 300. That is, the plurality of through holes 302 may be formed through the shower head 300. The plurality of through holes 302 may communicate a fluid from the upper mixing space A12 to the lower treatment space A21.

A hole 402 and a central gas inlet 410 may be formed in the ion blocker 400. The hole 402 may pass through an upper end and a lower end of the ion blocker 400. At least one central gas inlet 410 may be provided. A plurality of central gas inlets 410 may be provided. Each of the plurality of central gas inlets 410 may be connected to the second gas line 622. The central gas inlet 410 may supply the second gas G2 toward the mixing space A12. The central gas inlet 410 may communicate with the mixing space A12, but may be configured not to communicate with the upper plasma formation space A11.

A through hole 720 may be formed in the adsorption plate 700. At least one through hole 720 may be provided. For example, a plurality of through holes 720 may be provided. The through hole 720 may be formed to penetrate from the upper surface to the lower surface of the adsorption plate 700. The through hole 720 may be positioned to overlap the through hole 302 formed in the shower head 300 when viewed from the top. A diameter of the through hole 720 may be provided relatively larger than a diameter of the through hole 302. Optionally, the diameter of the through hole 720 may be provided to correspond to the diameter of the through hole 302.

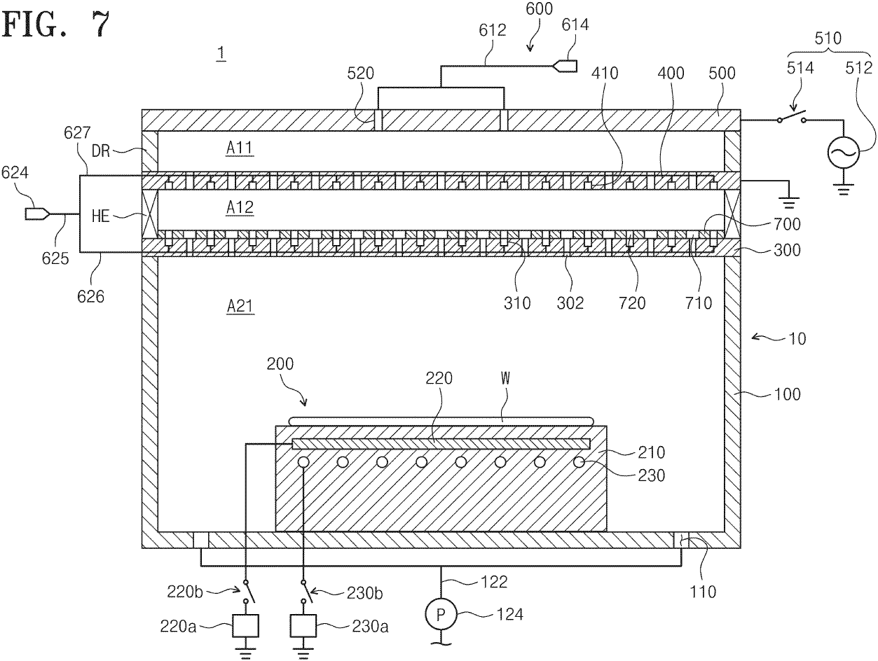

FIG. 7 is a diagram schematically illustrating the substrate treating apparatus according to another exemplary embodiment of FIG. 1. Referring to FIG. 7, the shower head 300 may have a substantially circular shape when viewed from the top. For example, the shower head 300 may be provided in a disk shape. According to the exemplary embodiment, the shower head 300 may be made of a material of stainless steel.

A through hole 302 may be formed in the shower head 300. A plurality of through holes 302 may be provided. The plurality of through holes 302 may be formed to extend from an upper surface to a lower surface of the shower head 300. That is, the plurality of through holes 302 may be formed through the shower head 300. The plurality of through holes 302 may communicate a fluid from the upper mixing space A12 to the lower treatment space A21.

A lower gas inlet 310 may be formed in the shower head 300. At least one lower gas inlet 310 may be provided. A plurality of lower gas inlets 310 may be provided. Each of the plurality of lower gas inlets 310 may be connected to a first branch line 646 to be described later. The lower gas inlet 310 may communicate with the gas hole 710 formed in the adsorption plate 700. The lower gas inlet 310 may supply the second gas G2 toward the mixing space A12. The lower gas inlet 310 may communicate with the mixing space A12, but may be configured not to communicate with the treatment space A21. The lower gas inlet 310 may be disposed between the plurality of through holes 302. That is, the lower gas inlet 310 may be formed at a position that does not overlap the plurality of through holes 302.

A hole 402 and a central gas inlet 410 may be formed in the ion blocker 400. The hole 402 may pass through an upper end and a lower end of the ion blocker 400. At least one central gas inlet 410 may be provided. A plurality of central gas inlets 410 may be provided. Each of the plurality of central gas inlets 410 may be connected to a second branch line 647 to be described later. The central gas inlet 410 may supply the second gas G2 toward the mixing space A12. The central gas inlet 410 may communicate with the mixing space A12, but may be configured not to communicate with the upper plasma formation space A11.

The second gas supply unit 620 may include a second gas line 622 and a second gas supply source 624. The second gas line 622 may include a main line 625, a first branch line 626, and a second branch line 627. One end of the main line 625 is connected to a second gas supply source 624 for supplying the second gas G2. The other end of the main line 645 may be branched into a first branch line 646 and a second branch line 625. The first branch line 646 may be connected to the lower gas inlet 310. The second gas G2 supplied to the lower gas inlet 310 through the main line 625 and the first branch line 626 may be supplied to the mixing space A12. The second branch line 647 may be connected to the central gas inlet 410. The second gas G2 supplied to the central gas inlet 410 through the main line 625 and the second branch line 627 may be supplied to the mixing space A12.

A gas hole 710 and a through hole 720 may be formed in the adsorption plate 700. At least one gas hole 710 may be provided. The gas hole 710 may pass through the adsorption plate in the vertical direction. The gas hole 710 may communicate with the lower gas inlet 310. The gas hole 710 may be formed at a position overlapping the lower gas inlet 310 at a location in which the adsorption plate 700 is coupled to the shower head 300. The gas hole 710 may allow the second gas G2 supplied from the lower gas inlet 310 to flow into the mixing space A12.

At least one through hole 720 may be provided. For example, a plurality of through holes 720 may be provided. The through hole 720 may be formed to penetrate from the upper surface to the lower surface of the adsorption plate 700. The through hole 720 may be positioned to overlap the through hole 302 formed in the shower head 300 when viewed from the top. A diameter of the through hole 720 may be provided relatively larger than a diameter of the through hole 302. Optionally, the diameter of the through hole 720 may be provided to correspond to the diameter of the through hole 302.

Unlike the above-described exemplary embodiment, the lower gas inlet 310 may be formed only in the edge region of the shower head 300. In addition, the central gas inlet 410 may be formed only in the central region of the ion blocker 400.

According to the exemplary embodiment of the present invention described with reference to FIGS. 6 and 7, the second gas G2 and the radical R may efficiently react in the mixing space A12. Accordingly, the amount of etchant E acting on the substrate W may be relatively increased than the amount of the radicals R acting on the substrate W.

The foregoing detailed description illustrates the present invention. Further, the above content shows and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

1. A substrate treating apparatus, comprising:
a chamber having an inner space;
a shower head for partitioning the inner space into an upper first zone and a lower second zone, and formed with a plurality of through holes;
a support unit for supporting a substrate in the second zone;
a gas supply unit for supplying gas to the first zone;
a plasma source for forming a plasma in the first zone by exciting the gas; and
an adsorption plate coupled to the shower head,
wherein a surface of the adsorption plate is provided with a material that adsorbs radicals contained in the plasma.

2. The substrate treating apparatus of claim 1, wherein the surface of the adsorption plate is provided with a material different from a material of the shower head.

3. The substrate treating apparatus of claim 2, wherein the gas contains a fluorine element, and
the radical contains a fluorine radical.

4. The substrate treating apparatus of claim 3, wherein the material includes nickel (Ni) or titanium (Ti), and
the adsorption plate adsorbs the fluorine radical.

5. The substrate treating apparatus of claim 4, wherein the gas further contains hydrogen ions, and
the adsorption plate adsorbs hydrogen ions in the gas.

6. The substrate treating apparatus of claim 1, wherein the adsorption plate is disposed to be in contact with an upper surface of the shower head.

7. The substrate treating apparatus of claim 6, wherein the adsorption plate is provided detachably from the shower head.

8. The substrate treating apparatus of claim 7, wherein a plurality of through holes is formed in the adsorption plate, and
the through hole is positioned to overlap the through hole when viewed from the top.

9. The substrate treating apparatus of claim 1, wherein the plasma source includes:
an ion blocker disposed above the shower head to partition the first zone into an upper plasma formation space and a lower mixing space, and grounded; and
an upper electrode which is disposed above the ion blocker and to which power is applied.

10. The substrate treating apparatus of claim 9, wherein the gas supply unit includes:
a first gas supply unit for supplying first gas to the plasma formation space; and
a second gas supply unit for supplying second gas to the mixing space, and
the plasma source excites the first gas to form the plasma, and
the ion blocker traps ions included in the plasma formed in the plasma formation space and allows radicals to pass to the mixing space.

11. A substrate treating apparatus, comprising:
a chamber having an inner space;
a support unit for supporting the substrate in the inner space;
an upper electrode to which high-frequency power is applied;
an ion blocker disposed under the upper electrode and grounded;
a shower head disposed under the ion blocker and above the support unit, and formed with a plurality of through holes;
a first gas supply unit for supplying first gas to a space between the upper electrode and the ion blocker;
a second gas supply unit for supplying second gas to a space between the ion blocker and the shower head; and
an adsorption plate provided on an upper surface of the shower head,
wherein a region between the upper electrode and the ion blocker is provided as a plasma formation space in which a plasma is formed from the first gas,
a region between the ion blocker and the shower head is provided as a mixing space in which radicals included in the plasma and the second gas react to form an etchant,
a substrate treating region, in which a substrate is treated by the etchant, is provided under the shower head, and
a surface of the adsorption plate is provided with a material capable of adsorbing specific ions contained in the first gas and the second gas, and radicals.

12. The substrate treating apparatus of claim 11, wherein the specific ion includes a hydrogen ion and
the radical includes a fluorine radical.

13. The substrate treating apparatus of claim 12, wherein the material includes nickel (Ni) or titanium (Ti).

14. The substrate treating apparatus of claim 12, wherein the adsorption plate is provided detachably from the shower head,
a plurality of through holes is formed in the adsorption plate, and
the through hole is positioned to overlap the through hole when viewed from the top, and
a diameter of the through hole is provided to be larger than a diameter of the through hole.

15-20. (canceled)
